(19) United States
(12) Patent Application Publication
(10) Pub. No.: US 2025/0087446 A1
(43) Pub. Date: Mar. 13, 2025

(54) Integrated Transformer Power Supply System for Multiphase Plasma Generation Devices

(71) Applicant: BEIJING ORIENTAL YANZHONG INDUSTRIAL DEVELOPMENT GROUP CO., LTD., Beijing (CN)

(72) Inventors: Enzhen DING, Ferntree Gully (AU); Angang LIU, Beijing (CN)

(21) Appl. No.: 18/549,359

(22) PCT Filed: May 18, 2023
(86) PCT No.: PCT/CN2023/094910

§ 371 Date: Sep. 7, 2023

(30) Foreign Application Priority Data
Jun. 1, 2022 (CN) 202210617218.6

(51) Int. Cl. H01J 37/24

(52) U.S. Cl. CPC H01J 37/241

(57) ABSTRACT

The invention discloses an integrated transformer power supply system for multiphase plasma generation devices, pertaining to the field of power supply for high-power multiphase plasma generators. The system comprises sequentially connected voltage regulation and frequency control unit, integrated transformer unit, and plasma generator. By changing the wiring configuration of the integrated transformer unit, a multiphase output power supply can be obtained to meet the different frequency requirements, voltage requirements, voltage phase requirements, steepness requirements, and other characteristics of various multiphase plasma generation devices. The system exhibits high flexibility, wide applicability, and can achieve the necessary conditions for efficient, robust, durable, and easily maintainable practical engineering solutions.

### TECHNICAL FIELD

The present invention relates to the power supply field of high-power multiphase plasma generators, more specifically, it involves an integrated transformer power supply system for multiphase plasma generation devices.

### BACKGROUND ART

Thermal plasma, as an efficient energy source, has found widespread applications in various fields. It has garnered significant attention recently due to its unique capabilities, including high temperature, high enthalpy, enhanced reaction kinetics, and rapid generation of chemically non-equilibrium materials. Furthermore, thermal plasma offers the ability to adjust the oxidizing or reducing atmosphere of chemical reactions according to specific requirements.

The AC arc generated by the AC power supply is a type of thermal plasma. Its high energy efficiency is mainly attributed to the elimination of the AC-to-DC conversion process. However, existing single-phase or three-phase AC arcs have limitations in terms of intermittent discharge during polarity switching and small discharge volume. These limitations hinder the further development of thermal plasma, leading to the introduction of multiphase AC arcs. Multiphase AC arcs occur between 4, 6, or even more than 12 electrodes and possess three major characteristics: high energy efficiency, large plasma volume, and low gas velocity. They find applications in various fields such as graphene manufacturing, non-alkali glass bead production, organic wastewater treatment, gas heating, and exhaust gas treatment. They can also be extensively used in thermal power generation, cement and building materials, chemical, metallurgical, and mining industries.

Transformer power supply, as the most essential system in a plasma generation device, must meet the requirements of high efficiency, robustness, durability, and easy maintenance for practical engineering applications. However, existing multiphase plasma integrated transformer power supply systems require separate design based on the specific needs of different multiphase plasma generation devices. For instance, the output of the multiphase power supply is commonly designed for 3-phase, 6-phase, 12-phase, or 24-phase configurations. However, for multiphase plasma generation devices that require 9-phase, 15-phase, and so on, a redesign is necessary. This results in lower overall system flexibility and limits its wide application in various multiphase plasma generation devices.

### INVENTION DESCRIPTION

The purpose of the present invention is to provide an integrated transformer power supply system for multiphase plasma generation devices. By altering the wiring configuration of the integrated transformer unit, it is capable of obtaining multiphase power supply according to specific requirements, thereby achieving the essential conditions of high efficiency, robustness, durability, and easy maintenance in practical engineering applications.

The embodiments of the present invention are achieved by implementing the following solutions:
The embodiments of this application provide an integrated transformer power supply system for multiphase plasma generation devices. The system includes sequentially connected voltage regulation and frequency control unit, integrated transformer unit, and plasma generator. The input terminal of the voltage regulation and frequency control unit is connected to an external AC power source, while the plasma generator utilizes the multiphase voltage outputted by the integrated transformer unit to generate multiphase plasma;
The integrated transformer unit comprises at least one set of main transformers, where the primary side of the main transformer is connected in a star configuration and connected to the voltage regulation and frequency control unit. The secondary side of the main transformer is connected to the plasma generator.

In some embodiments of the present invention, the voltage regulation and frequency control unit comprises a voltage regulation circuit and an auxiliary transformer, wherein the input terminal of the voltage regulation circuit is connected to an external AC power source, and the output terminal is connected to the primary side of the main transformer;

The one end of the primary side of the auxiliary transformer is connected to the star point of the primary side of the main transformer, while the other end of the primary side of the auxiliary transformer is grounded. The one end of the secondary side of the auxiliary transformer is connected to the secondary side of the main transformer, and the other end of the secondary side of the auxiliary transformer is connected to the ignition electrode of the plasma generator and grounded.

In some embodiments of the present invention, the two ends of the secondary side of the main transformer are respectively connected to the electrodes of the plasma generator, and the midpoint tap of the secondary side of the main transformer is connected to one end of the secondary side of the auxiliary transformer. The other end of the secondary side of the auxiliary transformer is connected to the ignition electrode of the plasma generator and grounded.

In some embodiments of the present invention, the output frequency of the auxiliary transformer is 2-4 times that of the main transformer.

In some embodiments of the present invention, the integrated transformer unit comprises a first set of main transformers and a second set of main transformers, wherein the primary side of the first set of main transformers is connected in a star configuration, and the primary side of the second set of main transformers is connected in a delta configuration, and the secondary sides of both the first and second sets of main transformers are connected to the plasma generator.

In some embodiments of the present invention, one end of the secondary side of both the first set of main transformers and the second set of main transformers is connected to the electrodes of the plasma generator, while the other end is grounded

In some embodiments of the present invention, the two ends of the secondary side of the first set of main transformers and the second set of main transformers are respectively connected to the electrodes of the plasma generator, and the midpoint taps of the secondary sides of the first set of main transformers and the second set of main transformers is grounded.

In some embodiments of the present invention, the primary coil turns of the second set of main transformers is \sqrt{3} times of that of the primary coil turns of the first set of main transformers.

In some embodiments of the present invention, a main transformer whose n groups of primary sides are in a Delta & Wye configuration is also included, wherein n is an integer greater than or equal to 1.

In some embodiments of the present invention, the voltage regulation and frequency control unit is a three-phase variable frequency converter.

Compared with the existing technologies, this application has at least the following advantages or beneficial effects:

The embodiments of the present invention provide an integrated transformer power supply system for multiphase plasma generation devices. The system comprises sequentially connected voltage regulation and frequency control unit, integrated transformer unit, and plasma generator. The voltage regulation and frequency control unit can be composed of a voltage regulation circuit and an auxiliary transformer, or it can be composed of a three-phase variable frequency converter. The integrated transformer unit includes at least one set of primary-side main transformers connected in a star configuration. When the auxiliary transformer is a triple-frequency transformer, its frequency is three times that of the main transformer. The high voltage output from the auxiliary transformer's secondary side is superimposed with the voltage output from each single-phase transformer in any set of main transformers. It is then used as the multiphase power input for the plasma generator to prevent arc extinction caused by the power zero-crossing during AC arc generation, thereby ensuring stability. At this point, multiple sets of main transformers and the auxiliary transformer form an (n+1)-phase integrated transformer power supply (where n is a multiple of 3), capable of providing multiphase power according to different requirements.

In addition, when the voltage regulation and frequency control unit directly uses a three-phase variable frequency converter, its output can be directly connected to the primary sides of multiple sets of main transformers. By changing the connection method of the primary sides of each set of main transformer, such as star connection, delta connection, and Delta & Wye configuration, different numbers of phases with phase differences can be obtained on the secondary side. This enables the integrated transformer power supply for plasma generators with more than 9 phases, such as 12, 15, 18, 24 . . . (Phases in multiples of 3).

### DESCRIPTION OF THE DRAWINGS

To provide a clearer understanding of the technical solution in the embodiment of the present invention, a brief introduction to the drawing used in the embodiment will be provided. It should be understood that these drawings only represent certain embodiments of the present invention and should not be considered as limiting the scope thereof. Ordinary skilled persons in the field can also obtain other related drawings based on these drawings without exercising inventive effort.

FIG. 1 is a schematic diagram in an embodiment of the integrated transformer power supply system for multiphase plasma generation device provided by the present invention;

FIG. 2 is a schematic diagram in another embodiment of the integrated transformer power supply system for multiphase plasma generation device provided by the present invention;

FIG. 3 is a schematic diagram of electrode arrangement in an embodiment of the integrated transformer power supply system for multiphase plasma generation device provided by the present invention;

FIG. 4 is a schematic diagram of the integrated transformer unit in an embodiment of the integrated transformer power supply system for multiphase plasma generation device provided by the present invention;

FIG. 5 is a schematic diagram of the integrated transformer unit in an embodiment of the integrated transformer power supply system for multiphase plasma generation device provided by the present invention.

The reference numbers are: 1. The voltage regulation and frequency control unit; 2. Integrated transformer unit; 21. The first set of main transformers; 22. The second set of main transformers; 3. Plasma generator; 31. Plasma generator shell; 32. Electrodes; 33. Ignition electrodes.

### DETAILED IMPLEMENTATION METHODS

In order to provide a clear description of the objectives, technical solutions, and advantages of the embodiment of the present application, the following will combine the drawing of the embodiments of the present application to describe the technical solutions in a clear and complete manner. It is evident that the described embodiment is only a part of the embodiments of the present application, not all of them. The components of the embodiment of the present application described and illustrated in the drawing can be arranged and designed in various configurations.

Therefore, the detailed description of the embodiments of the present application provided in the drawing is not intended to limit the scope of the claimed invention, but only represents selected embodiments of the present application. Based on the embodiments disclosed in this application, all other embodiments that ordinary skilled persons can obtain without exercising inventive effort are within the scope of protection of the present application.

### EMBODIMENTS

With reference to the drawings, detailed explanations of some embodiments of the present application are provided below. Unless there is a conflict, the following embodiments and their respective features can be combined with each other.

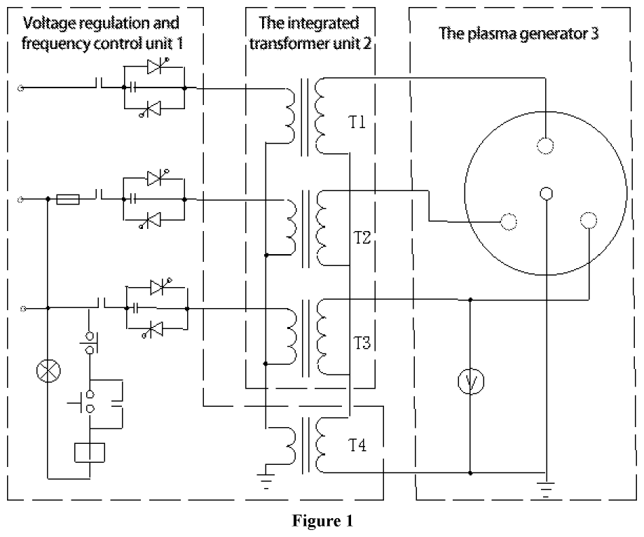

Please refer to FIG. 1. The embodiments of the present application provide an integrated transformer power supply system for multiphase plasma generation devices. The system includes sequentially connected the voltage regulation and frequency control unit 1, the integrated transformer unit 2, and the plasma generator 3. The input terminal of the voltage regulation and frequency control unit 1 is connected to an external AC power source, while the plasma generator 3 utilizes the multiphase voltage outputted by the integrated transformer unit 3 to generate multiphase plasma.

The integrated transformer unit 2 comprises at least one set of main transformers, where the primary side of the main transformer is connected in a star configuration and connected to the voltage regulation and frequency control unit 1. The secondary side of the main transformer is connected to the plasma generator 3.

Furthermore, the voltage regulation and frequency control unit 1 comprises a voltage regulation circuit and an auxiliary transformer, wherein the input terminal of the voltage regulation circuit is connected to an external AC power source, and the output terminal is connected to the primary side of the main transformer;

The one end of the primary side of the auxiliary transformer is connected to the star point of the primary side of the main transformer, while the other end of the primary side of the auxiliary transformer is grounded. The one end of the secondary side of the auxiliary transformer is connected to the secondary side of the main transformer, and the other end of the secondary side of the auxiliary transformer is connected to the ignition electrode 33 of the plasma generator 3 and grounded.

In the technical solution provided in the present embodiment, a set of main transformers is composed of three single-phase transformers of the same specifications. For example, when the integrated transformer unit 2 includes a set of main transformers, the three single-phase transformers are referred to as single-phase transformer T1, single-phase transformer T2, and single-phase transformer T3. The primary sides of these transformers are connected in a star configuration and connected to the voltage regulation circuit. The secondary sides are used to output a multiphase power supply, which is then connected to the electrodes 32 of the plasma generator 3, providing a multiphase power supply for generating an alternating current arc in the plasma generator 3. However, during the discharge process of the alternating current, the current passes through zero twice within one cycle, which can cause instability in the discharge and lead to arc extinguishment. To mitigate this issue, an auxiliary transformer T4 can be employed. Specifically, one end of the primary side of the auxiliary transformer T4 is connected to the star point of the primary side of the main transformer, while the other end is grounded. One end of the secondary side of the auxiliary transformer T4 is connected to the secondary sides of single-phase transformers T1, T2, and T3, and the other end is connected to the ignition electrode 33 of the plasma generator 3 and grounded. The other ends of the secondary sides of single-phase transformers T1, T2, and T3 serve as the three-phase power supply output for the plasma generator 3. The frequency of the auxiliary transformer T4 can be 2-4 times the frequency of single-phase transformers T1, T2, and T3, with the optimal ratio being 3 times. Additionally, there exists a phase difference between each pair of transformers, allowing the high voltage output from the secondary side of the auxiliary transformer to be superimposed with the voltage output of any single-phase transformer. This combined output serves as the multiphase power supply input for the plasma generator 3, ensuring stable generation of the AC arc. In essence, the auxiliary transformer T4 functions as an arc igniter. Overall, the single-phase transformers T1, T2, and T3, along with the auxiliary transformer T4, constitute a “3+1 phase” self-igniting integrated transformer power supply, capable of outputting three-phase power. Furthermore, by increasing the number of main transformers, it is possible to achieve multiphase outputs, such as 9-phase or 12-phase.

As an example, the entire system can be powered by an external three-phase AC power source. The phase voltage of the three-phase AC power supply can range from 220V to 2,500V, and the frequency can range from 50 Hz to 5,000 Hz. The no-load output phase voltage of the entire system can range from 200V to 120 kV, while the load output phase voltage can range from 50V to 20 kV. Additionally, the auxiliary transformer T4 can be a small-sized single-phase transformer with steep voltage drop characteristics. Its capacity only needs to account for 10% of the total system capacity, and the primary side voltage of the auxiliary transformer is 0.3 times the transmission line voltage of the main transformer.

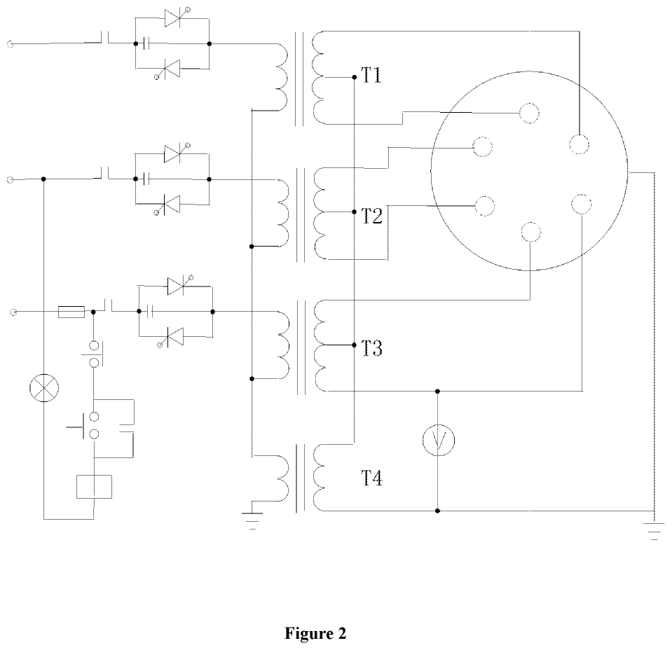

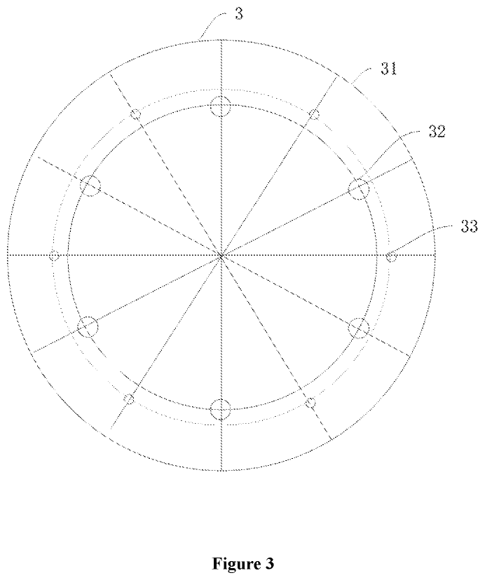

Please refer to FIG. 2 and FIG. 3. In some embodiments of the present invention, the two ends of the secondary side of the main transformer are respectively connected to the electrodes 32 of the plasma generator 3, and the midpoint tap of the secondary side of the main transformer is connected to one end of the secondary side of the auxiliary transformer. The other end of the secondary side of the auxiliary transformer is connected to the ignition electrode 33 of the plasma generator 3 and grounded.

In the technical solution provided in the present embodiment, one end of the secondary side of the auxiliary transformer T4 is connected to the midpoint taps of single-phase transformers T1, T2, and T3 respectively, and the other end is connected to the ignition electrode 33 of the plasma generator 3 and grounded. The ignition electrode 33 and the plasma generator shell 31 are connected together. At this point, both ends of single-phase transformers T1, T2, and T3 are connected to electrode 32 of the plasma generator 3, serving as a 6-phase power supply for the plasma generator 3 to ensure stable generation of the AC. Overall, the single-phase transformers T1, T2, and T3, along with the auxiliary transformer T4, constitute a “6+1 phase” self-igniting integrated transformer power supply, capable of outputting six-phase power. Furthermore, by increasing the number of main transformers, it is possible to achieve multiphase outputs, such as 12-phase or 24-phase.

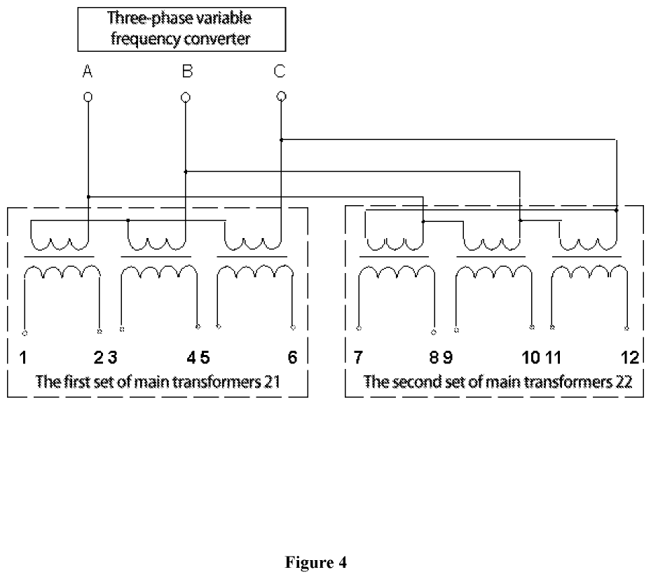

Please refer to FIG. 4. In some embodiments of the present invention, the voltage regulation and frequency control unit 1 can directly use a three-phase variable frequency converter, and the integrated transformer unit 2 comprises a first set of main transformers 21 and a second set of main transformers 22, wherein the primary side of the first set of main transformers 21 is connected in a star configuration, and the primary side of the second set of main transformers 22 is connected in a delta configuration, and the secondary sides of the first set of main transformers 21 and the second set of main transformers 22 are connected to the plasma generator 3.

Moreover, one end of the secondary sides of the first set of main transformers 21 and the second set of main transformers 22 is connected to electrode 32 of the plasma generator 3, while the other end is grounded.

In the technical solution provided in the present embodiment, the voltage regulation and frequency control unit 1 can directly use a three-phase variable frequency converter, which supplies the integrated transformer unit 2 with basic power. For example, a three-phase AC power with an output voltage of 380V and a frequency of 3,000 Hz. As an example, the integrated transformer unit 2 comprises the first set of main transformers 21 and the second set of main transformers 22, totaling 6 single-phase transformers. Therefore, there are a total of 12 terminals on the secondary side, labeled as terminals 1 to 12. The primary side of the first set of main transformers 21 is connected in a star configuration, while the primary side of the set group of main transformers 22 is connected in a delta configuration. Then, by shorting and grounding terminals 2, 4, 6, 8, 10, and 12 on the secondary side, and using terminals 1, 3, 5, 7, 9, and 11 as the outputs of the 6 phases, they are connected to electrode 32 of the plasma generator 3 to generate a 6-phase AC arc.

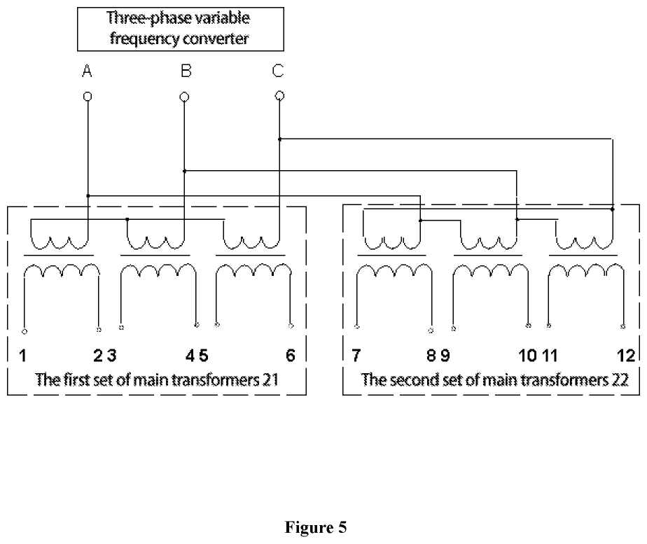

Please refer to FIG. 5. In some embodiments of the present invention, the two ends of the secondary sides of the first set of main transformers 21 and the second set of main transformers 22 are respectively connected to the electrodes 32 of the plasma generator 32, and the midpoint taps of the secondary sides of the first set of main transformers 21 and the second set of main transformers 22 is grounded.

In the technical solution provided in the present embodiment, the primary side of the first set of main transformers 21 remains connected in a star configuration, and the primary side of the second set of main transformers 22 remains connected in a delta configuration. Then, by shorting and grounding the midpoints taps of the 6 single-phase transformers, and using terminals 1 to 12 as the outputs of the 12 phases, they are connected to electrode 32 of the plasma generator 3 to generate a 12-phase AC arc.

In some embodiments of the present invention, the primary coil turns of the second set of main transformers 22 is 3 times of that of the primary coil turns of the first set of main transformers 21.

In the technical solution provided in the present embodiment, when the integrated transformer unit 2 includes two sets of main transformers, in order to avoid circulating currents between the single-phase transformers and reduce inefficiency, the primary coil turns of the second set of main transformers 22, whose primary side is connected in a delta configuration, can be set to 3 times the primary coil turns of the first set of main transformers 21, whose primary side is connected in a star configuration.

In some embodiments of the present invention, a main transformer whose n groups of primary sides are in a Delta & Wye configuration is also included, wherein n is an integer greater than or equal to 1.

Please refer to FIG. 4 and FIG. 5. By using two sets of main transformers (with the primary side of the first set of main transformers 21 connected in a star configuration and the primary side of the second set of main transformers 22 connected in a delta configuration), it is already possible to output a 6-phase or 12-phase power supply. Building upon this, by adding an additional set of main transformers, a 9-phase high-voltage intermediate frequency (IF) output power supply can be obtained. The primary side of this additional set of main transformers can be connected in a modified delta configuration, allowing for a 9-phase output on the secondary side with different phase differences. Moreover, by increasing the number of groups of main transformers with the primary side connected in a Delta & Wye configuration, it is possible to obtain a multiphase output power supply on the secondary side, such as 12, 15, 18, 24 . . . (Phases in multiples of 3), to meet the different frequency requirements, voltage requirements, voltage phase requirements, and steepness characteristics of various multiphase plasma generation devices. By altering the wiring configuration, a multiphase power supply can be obtained, maintaining a high degree of flexibility and enabling wide applications. Additionally, there are different phase differences between each phase. When phase 1 passes through zero, the other 5 phases do not pass through zero, ensuring continuous and stable arcs by alternating zero crossings among the phases.

Based on aforementioned, the embodiments of the present invention provide an integrated transformer power supply system for multiphase plasma generation devices. The system comprises sequentially connected the voltage regulation and frequency control unit 1, the integrated transformer unit 2, and the plasma generator 3. The voltage regulation and frequency control unit 1 can be composed of a voltage regulation circuit and an auxiliary transformer, or it can be composed of a three-phase variable frequency converter. The integrated transformer unit 2 includes at least one set of primary-side main transformers connected in a star configuration. When the auxiliary transformer is a triple-frequency transformer, its frequency is three times that of the main transformer. The high voltage output from the auxiliary transformer's secondary side is superimposed with the voltage output from each single-phase transformer in any set of main transformers. It is then used as the multiphase power input for the plasma generator 3 to prevent arc extinction caused by the power zero-crossing during AC arc generation, thereby ensuring stability. At this point, multiple sets of main transformers and the auxiliary transformer form an (n+1)-phase integrated transformer power supply (where n is a multiple of 3), capable of providing multiphase power according to different requirements.

In addition, when the voltage regulation and frequency control unit 1 directly uses a three-phase variable frequency converter, its output can be directly connected to the primary sides of multiple sets of main transformers. By changing the connection method of the primary sides of each set of main transformer, such as star connection, delta connection, and Delta & Wye configuration, different numbers of phases with phase differences can be obtained on the secondary side. This enables the integrated transformer power supply for plasma generators with more than 9 phases, such as 12, 15, 18, 24 . . . (Phases in multiples of 3).

Overall, this system is composed of a basic power supply and multiple single-phase transformers combined together. By utilizing transformer integration with modularized wiring configurations, various multiphase power supplies can be obtained to meet different requirements including high efficiency, robustness, durability, and easy maintenance in practical engineering applications.

The aforementioned are merely preferred embodiments of the present application and should not be construed as limiting the scope of the application. For those skilled persons in this field, this application may subject to various modifications and changes. Any modifications, equivalent substitutions, improvements, etc., made within the spirit and principles of the present application should be included within the scope of protection of the present application.

For those skilled persons in this field, it is evident that the present application is not limited to the details of the exemplary embodiments described above. Moreover, it is possible to implement the present application in other specific forms without departing from the spirit or essential characteristics of the present application. Therefore, from whatever perspective, the embodiments should be considered as illustrative and non-restrictive. The scope of the present application is defined by the appended claims rather than the above description, and thus, it aims to encompass all variations falling within the meaning and scope of the equivalent elements of the claims. Any references to specific drawings in the claims should not be construed as limiting the scope of the claims.

1. A power supply system with an integrated transformer for a multiphase plasma generation device, featuring sequentially connected voltage regulation and frequency control unit, integrated transformer unit, and plasma generator. The input terminal of the voltage regulation and frequency control unit is connected to an external AC power source, while the plasma generator utilizes the multiphase voltage outputted by the integrated transformer unit to generate multiphase plasma;
The integrated transformer unit comprises at least one set of main transformers, where the primary side of the main transformer is connected in a star configuration and connected to the voltage regulation and frequency control unit. The secondary side of the main transformer is connected to the plasma generator.

2. A integrated transformer power supply system for a multiphase plasma generation device as claimed in claim 1 is characterized in that the voltage regulation and frequency control unit comprises a voltage regulation circuit and an auxiliary transformer, wherein the input terminal of the voltage regulation circuit is connected to an external AC power source, and the output terminal is connected to the primary side of the main transformer;
The one end of the primary side of the auxiliary transformer is connected to the star point of the primary side of the main transformer, while the other end of the primary side of the auxiliary transformer is grounded. The one end of the secondary side of the auxiliary transformer is connected to the secondary side of the main transformer, and the other end of the secondary side of the auxiliary transformer is connected to the ignition electrode of the plasma generator and grounded.

3. A integrated transformer power supply system for a multiphase plasma generation device as claimed in claim 2 is characterized in that the two ends of the secondary side of the main transformer are respectively connected to the electrodes of the plasma generator, and the midpoint tap of the secondary side of the main transformer is connected to one end of the secondary side of the auxiliary transformer. The other end of the secondary side of the auxiliary transformer is connected to the ignition electrode of the plasma generator and grounded.

4. An integrated transformer power supply system for a multiphase plasma generation device as claimed in claim 2 is characterized in that the output frequency of the auxiliary transformer is 2-4 times that of the main transformer.

5. An integrated transformer power supply system for a multiphase plasma generation device as claimed in claim 1 is characterized in that the integrated transformer unit comprises a first set of main transformers and a second set of main transformers, wherein the primary side of the first set of main transformers is connected in a star configuration, and the primary side of the second set of main transformers is connected in a delta configuration, and the secondary sides of both the first and second sets of main transformers are connected to the plasma generator.

6. An integrated transformer power supply system for a multiphase plasma generation device as claimed in claim 5 is characterized in that one end of the secondary side of both the first set of main transformers and the second set of main transformers is connected to the electrodes of the plasma generator, while the other end is grounded.

7. An integrated transformer power supply system for a multiphase plasma generation device as claimed in claim 5 is characterized in that the two ends of the secondary side of the first set of main transformers and the second set of main transformers are respectively connected to the electrodes of the plasma generator, and the midpoint taps of the secondary sides of the first set of main transformers and the second set of main transformers is grounded.

8. An integrated transformer power supply system for a multiphase plasma generation device as claimed in claim 5 is characterized in that the primary coil turns of the second set of main transformers is \sqrt{3} times of that of the primary coil turns of the first set of main transformers.

9. An integrated transformer power supply system for multiphase plasma generation device as claimed in claim 5 is characterized by further comprising a main transformer whose n groups of primary sides are in a Delta & Wye configuration, wherein n is an integer greater than or equal to 1.

10. An integrated transformer power supply system for a multiphase plasma generation device as claimed in claim 5 is characterized in that the voltage regulation and frequency control unit is a three-phase variable frequency converter.
